(19) United States
(12) Patent Application Publication
(10) Pub. No.: US 2013/0148275 A1
(43) Pub. Date: Jun. 13, 2013

(54) PLUG AND ELECTRONIC DEVICE USING SAME

(71) Applicant: HAI-QING ZHOU, Shenzhen City (CN)

(72) Inventor: HAI-QING ZHOU, Shenzhen City (CN)

(73) Assignees: HON HAI PRECISION INDUSTRY CO., LTD., Tu-Cheng (TW); HONG FU PRECISION INDUSTRY(ShenZhen) CO., LTD., Chenzhen City (CN)

(21) Appl. No.: 13/531,047

(22) Filed: Jun. 22, 2012

(30) Foreign Application Priority Data
Dec. 7, 2011 (CN) 201110402778.1

(51) Int. Cl. H01R 13/52; H05K 7/00

(52) U.S. Cl. 361/679.01; 439/892

(57) ABSTRACT

A plug for a connecting port of an electronic device to prevent the connecting port from moisture and dust and includes a base, a protection wall, and a fixing arm. The protection wall is an enclosing circular wall extending along a periphery of the base and defines a receiving space. The fixing arm extends outwards from an outer side surface of the protection wall. The fixing arm includes a connecting part and a pair of fastening pieces formed at an end of the fixing arm away from the protection wall. The connecting part connects with the protection wall. The fastening pieces extend outwards from a surface of the connecting part away from the base.

### TECHNICAL FIELD

The disclosure generally relates to plugs, and particularly, to a plug capable of protecting a connecting port of an electronic device.

### DESCRIPTION OF RELATED ART

Electronic devices usually includes many connecting ports. However, when not in use, the connecting ports are expose to the air and are easily damaged by moisture and dust that may accumulate in the connecting ports.

Therefore, there is room for improvement in the art.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is an isometric view of an electronic device in accordance with one embodiment of present disclosure.

FIG. 2 is an exploded, isometric view of the electronic device of FIG. 1.

FIG. 3 is an enlarged, isometric view of an interface module of the electronic device of a portion III of FIG. 2.

FIG. 4 is an isometric view of a plug of the electronic device of FIG. 1.

FIG. 5 is an isometric view of the plug of FIG. 4, viewed from another angle.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

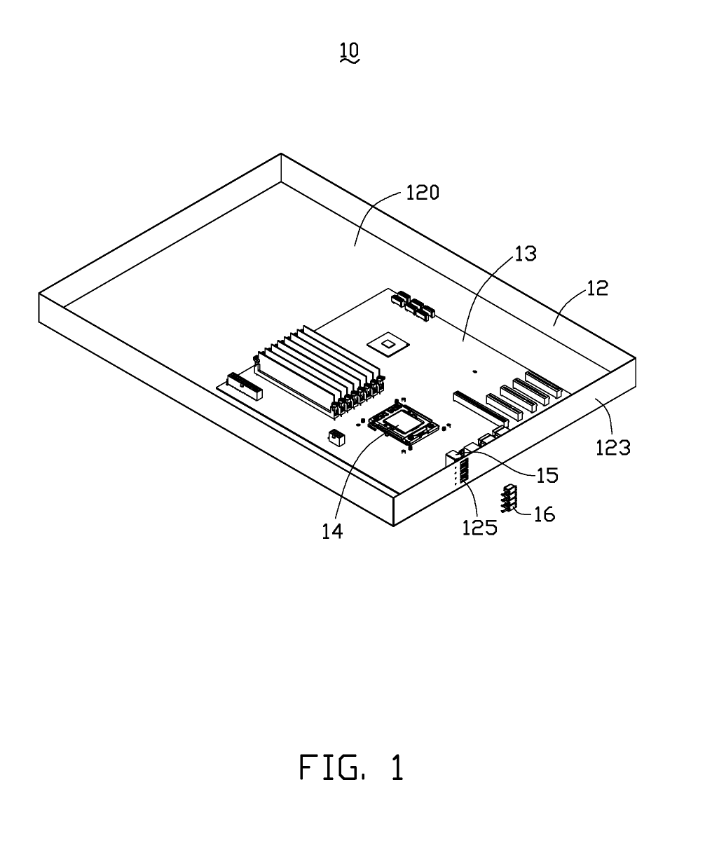

Referring to FIGS. 1-3, an electronic device 10 in accordance with an exemplary embodiment of the present disclosure is disclosed. The electronic device 10 includes a case 12, a circuit board 13, a processor 14, an interface module 15, and a number of plugs 16. The circuit board 13 is received in the case 12. The processor 14 is assembled on the circuit board 13. The interface module 15 is mounted on the circuit board 13 and electrical connected to the processor 14. The processor 14 may be a central processing unit. The electronic device 10 may be a computer, a television, or an electronic book reader.

The case 12 includes a bottom board 120 and a number of sidewalls 123. The sidewalls 123 are connected with each other. Ends of the sidewalls 123 are perpendicular connected to the bottom board 120. The circuit board 13 is set near one of the sidewalls 123. The interface module 15 aligns with a periphery of the circuit board 13 and is closely adjacent to the sidewall 123. The interface module 15 includes a number of connecting ports 150. The connecting ports 150 are overlapped along a direction perpendiculary to the bottom board 120. The sidewall 123 defines a number of openings 125 corresponding to the connecting ports 150 and further defines a number of fasten holes 177 near the openings 125. The connecting ports 150 are exposed to the air via the openings 125. In one embodiment, the interface module 15 includes four connecting ports 150. The sidewall 123 defines four openings 125 corresponding to the connecting ports 150.

Each of the connecting ports 150 includes a receiving groove 152 and a number of connecting terminals 154 received in the receiving groove 152. The connecting terminals 154 are configured for transmitting electrical signals with an external equipment (not shown). The plugs 16 are inserted into the available connecting ports 150 for protecting the connecting ports from moisture and dust.

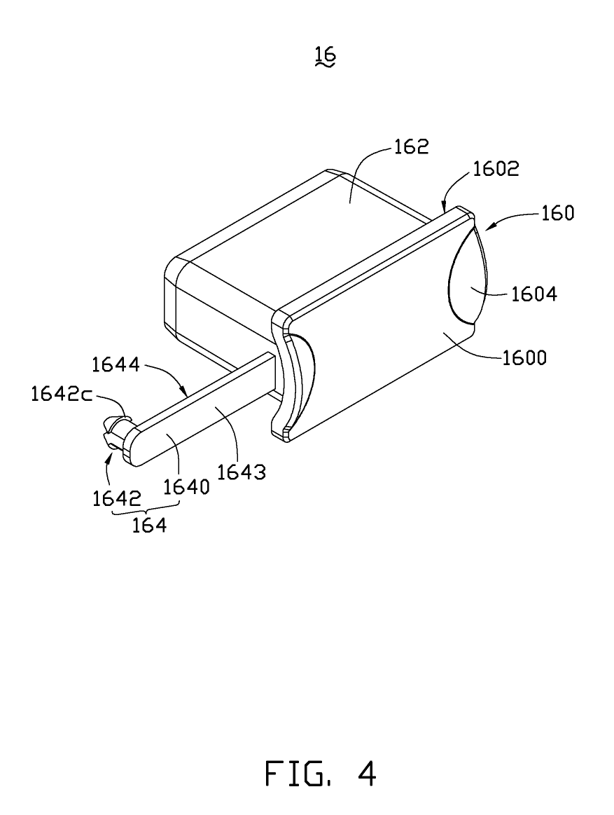

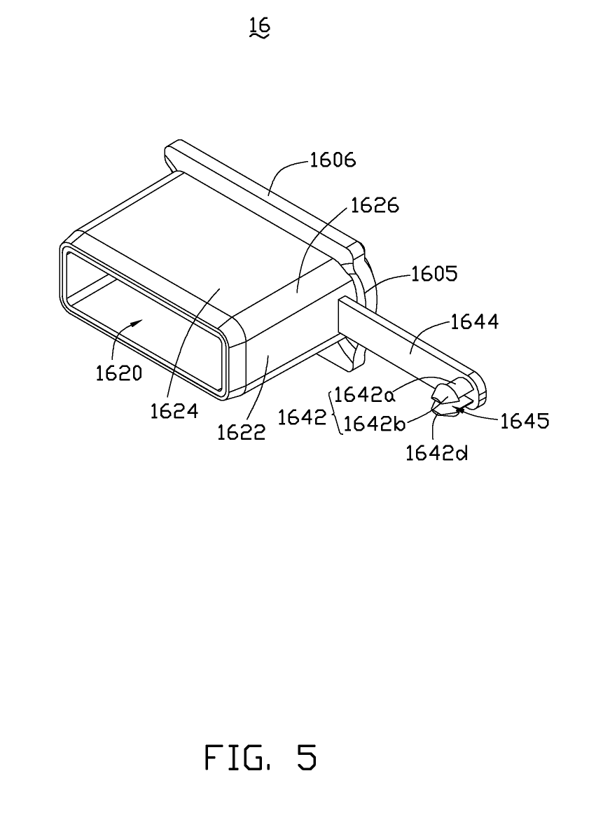

Referring to FIGS. 4-5, each of the plugs 16 includes a base 160, a protection wall 162 extending from one side of the base 160, and a fixing arm 164 extending from an outer side surface 1620 of the protection wall 162.

The base 160 may be a thin plate and includes an outer surface 1600, an inner surface 1602 parallel to the outer surface 1600, and a pair of bumps 1604 extending outwards at two opposite sides of the outer surface 1600. The protection wall 162 perpendicularly extends from a periphery of the inner surface 1602. The protection wall 162 is an annular wall which defines a receiving space 1620. The shape and size of the protection wall 162 are suitable for being received by the connecting port. The shape and size of the outer surface 1600 may be suitable for coving the opening of the sidewall of the case 123. In one embodiment, the base 160 is substantially rectangular. The protection wall 162 includes a pair of short portions 1622 corresponding to a pair of short sides 1605 of the base 160 and a pair of long portions 1624 corresponding to a pair of long sides 1606 of the base 160. The short portions 1622 are connected to the long portions 1624 via circular corners 1626. The bumps 1604 are correspondingly formed at the short sides of the base 160.

The fixing arm 164 extends along a longitudinal direction of the base 160. In one embodiment, the fixing arm 164 extends perpendicularly from one of the short portions 1622 of the protection wall 162. The fixing arm 164 includes a connecting part 1640 connecting with the protection wall 162 and a pair of fastening pieces 1642. The connecting part 1640 is an elongated thin board and includes an upper surface 1643 and a lower surface 1644 parallel to the upper surface 1643. The fastening pieces 1642 perpendicular extend from the lower surface 1644 at an end of the connecting part 1643 away from the protection wall 162. The pair of fastening pieces 1642 are spaced by a gap 1645 therebetween. Each of the fastening pieces 1642 includes a holding post 1642a and a fasten block 1642b. The fasten block 1642b is formed at an end of the holding post 1642a away from the lower surface 1644. The fasten block 1642b includes a first end surface 1642c connecting with the holding post 1642a and a second end surface 1642d away from the holding post 1642a. In one embodiment, the fastening pieces 1642 are made of resilient material. The holding post 1642a is a semi-cylinder. The fasten block 1642b is a semi-cone. The diameter of the fasten block 1642b is gradually reduced from the first end surface 1642c to the second end surface 1642d. The diameter of the first end surface 1642c is greater than the diameter of the holding post 1642a.

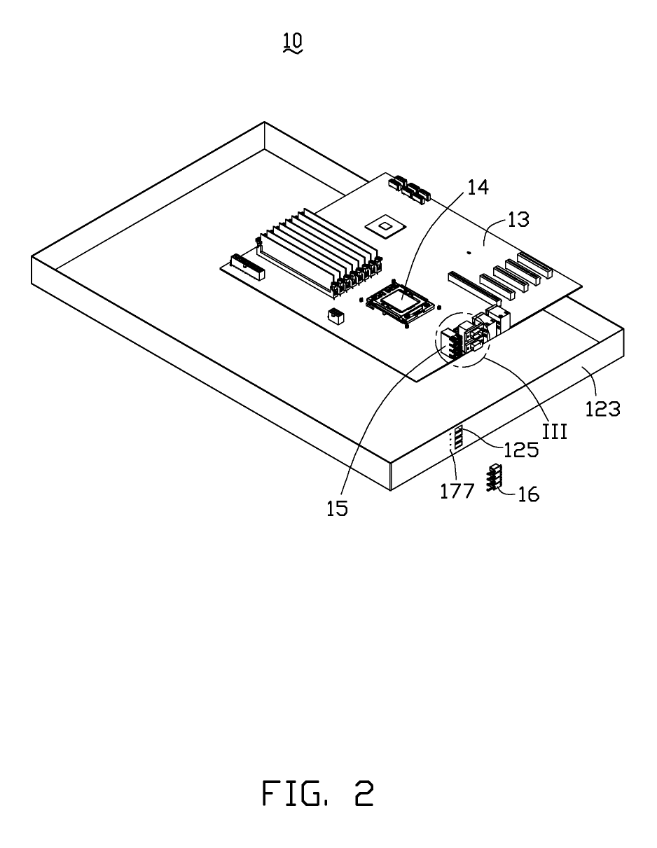

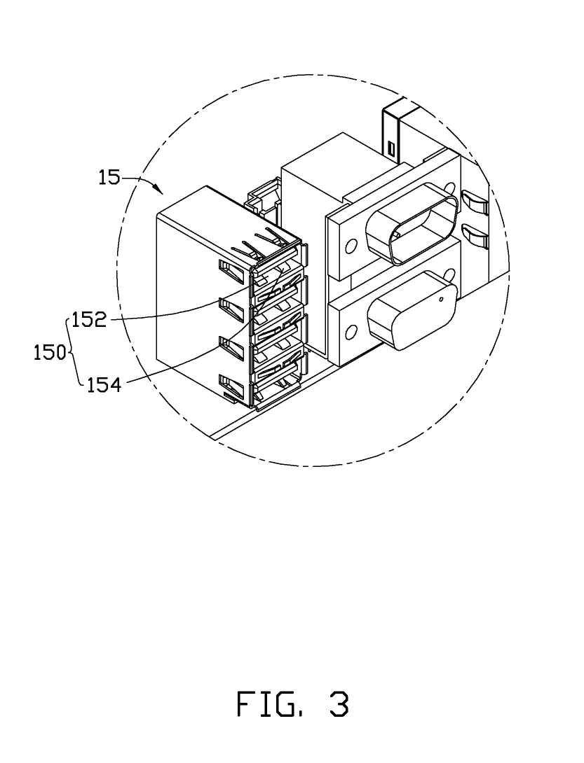

Also referring to FIGS. 2 and 3, when the plug 16 is inserted into the connecting port 150, the protection wall 162 is tightly engaged with the inner side surface of the receiving groove 152. The connecting terminals 154 are accommodated in the receiving space 1620 and are embraced in the protection wall 162. The base 160 covers the opening 125. The fastend pieces 1642 are inserted into the corresponding fasten hole 177. The first end surface 1642c of the fasten block 1642b resists against a periphery of the fasten hole 177 to prevent the plug 16 from escaping out of the connecting port 150.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A plug for a connecting port of an electronic device to protect the connecting port from moisture and dust, comprising:
a base;
an enclosing cylindrical protection wall extending along a periphery of the base and defining a receiving space; and
a fixing arm extending outwards from an outer side surface of the protection wall and comprising a connecting part and a pair of fastening pieces formed at an end of the fixing arm away from the protection wall;
wherein the connecting part connecting with the protection wall, the fastening pieces extending outwards from a surface of the connecting part away from the base.

2. The plug of claim 1, wherein the base comprises an outer surface, an inner surface parallel to the outer surface, and a pair of bumps extending outwards at two opposite sides of the outer surface, the protection wall extends outwards from the outer surface.

3. The plug of claim 2, wherein the base is rectangular, the pair of the bumps are correspondingly formed at a pair of short sides of the base.

4. The plug of claim 3, wherein the protection wall comprises a pair of short portions corresponding to the short sides of the base and a pair of long portions corresponding to a pair of long sides of the base, the short portion is connected to the long portion via a circular corner.

5. The plug of claim 1, wherein the connecting part is an elongated board extending along a longitudinal direction of the base.

6. The plug of claim 1, wherein the pair of fastening pieces are spaced by a gap.

7. The plug of claim 1, wherein each of the fastening pieces comprises a holding post and a fasten block formed at an end of the holding post away from the connecting part, the fasten block comprises a first end surface connecting with the holding post and a second end surface away from the holding post, the diameter of the first end surface is greater than the diameter of the holding post.

8. The plug of claim 7, wherein the diameter of the fasten block is gradually reduced from the first end surface to the second end surface.

9. An electronic device comprising:
a case comprising a sidewall, the sidewall defining an opening and a fasten hole near the opening;
a circuit board set in the case, the circuit board comprising a connecting port, the connecting port located corresponding to the opening to expose out of the case via the opening; and
a plug be capable of covering the connecting port, the plug comprising:
a base capable of covering an exposed portion of the connecting port;
a protection wall extending from the base; and
a fixing arm connecting with one of the base and the protection wall , and the fixing arm comprising at least one fastening piece formed at an end of the fixing arm away from the protection wall;
wherein the fastend piece is inserted into the fasten hole to attach the plug to the sidewall, the protection wall is capable of being inserted into the connecting port and removed from the connecting port, when the protection wall is inserted into the connecting port, the base covers the whole exposed portion of the connecting port, when the protection wall is removed from the connecting port, the exposed portion exposes again, and the cover is hung on the sidewall by the fixing arm.

10. The electronic device of claim 9, wherein the base comprises an outer surface, an inner surface parallel to the outer surface, and a pair of bumps extending outwards at two opposite sides of the outer surface, the protection wall extends outwards from the outer surface.

11. The electronic device of claim 10, wherein the base is rectangular, the pair of the bumps are correspondingly formed at a pair of short sides of the base.

12. The electronic device of claim 11, wherein the protection wall comprises a pair of short portions corresponding to the short sides of the base and a pair of long portions corresponding to a pair of long sides of the base, the short portion is connected to the long portion via a circular corner.

13. The electronic device of claim 9, wherein the connecting part is an elongated board extending along a longitudinal direction of the base.

14. The electronic device of claim 9, wherein the fixing arm comprises a pair of fastening pieces, the fastening pieces are spaced by a gap.

15. The electronic device of claim 14, wherein each of the fastening pieces comprises a holding post and a fasten block formed at an end of the holding post away from the connecting part, the fasten block comprises a first end surface connecting with the holding post and a second end surface away from the holding post, the diameter of the first end surface is greater than the diameter of the holding post.

16. The electronic device of claim 15, wherein the diameter of the fasten block is gradually reduced from the first end surface to the second end surface.
